(19) United States
(12) Patent Application Publication
(10) Pub. No.: US 2025/0273575 A1
(43) Pub. Date: Aug. 28, 2025

(54) GATE CONTACT OVER THE EDGE OF THE GATE CHANNEL

(71) Applicant: INTERNATIONAL BUSINESS MACHINES CORPORATION, ARMONK, NY (US)

(72) Inventors: Sagarika Mukesh, Albany, NY (US); Tao Li, Slingerlands, NY (US); Ruilong Xie, Niskayuna, NY (US); Feng Liu, Niskayuna, NY (US)

(21) Appl. No.: 18/587,910

(22) Filed: Feb. 26, 2024

(51) Int. Cl. H01L 23/535; H01L 21/768; H01L 23/528; H01L 29/06; H01L 29/417; H01L 29/423; H01L 29/66; H01L 29/775

(52) U.S. Cl. CPC H01L 23/535; H01L 21/76805; H01L 21/76895; H01L 23/5286; H10D 30/014; H10D 30/43; H10D 30/6729; H10D 30/6735; H10D 62/121; H10D 64/017

(57) ABSTRACT

A semiconductor device includes a gate contact over a first gate channel of two adjacent gate channels, and a first dielectric layer encapsulating a lower portion of a second dielectric layer and covering a first side of the second dielectric layer. The first dielectric layer is extended vertically between two adjacent gate channels, and the gate contact is connected to an upper portion of the first side of the second dielectric layer.

### BACKGROUND

### Technical Field

The present disclosure generally relates to transistors and, more particularly, to transistors with gate contacts over the edge of the gate channel structure and methods of creation thereof.

### Description of the Related Art

Routability is the ability to pattern interconnects and transistors in an integrated circuit (IC) while meeting layout design constraints. As transistors and chip components have become smaller, routability has emerged as a limiting factor dictating chip performance and fabrication success. Since manual routing is impossible, the importance of the high routability is highlighted. In some instances, interconnect delays dominate circuit timing instead of transistor speeds, and wiring complexity impacts signal propagation delays. In essence, achieving timing, power and signal integrity goals for billion transistor designs can be hindered in the absence of a robust, redundant routing architecture and thorough analysis of routability.

### SUMMARY

According to an embodiment, a semiconductor device includes a gate contact over a first gate channel of two adjacent gate channels, and a first dielectric layer encapsulating a lower portion of a second dielectric layer and covering a first side of the second dielectric layer. The first dielectric layer is extended vertically between two adjacent gate channels, and the gate contact is connected to an upper portion of the first side of the second dielectric layer.

In some embodiments, the first dielectric layer is connected to the second gate channel of the two adjacent gate channels.

In some embodiments, the gate contact further covers portions of a top surface of the second dielectric layer.

In some embodiments, the semiconductor device includes a first self-aligned contact (SAC) dielectric cap over the first gate channel of the two adjacent gate channels, and a second SAC dielectric cap over the second gate channel of the two adjacent gate channels. The gate contact is connected to the first SAC dielectric cap.

In seem embodiments, a top surface of portions of the first dielectric layer, a top surface of the second dielectric layer, a top surface of the first SAC dielectric cap, and a top surface of the second SAC dielectric cap are coplanar.

In some embodiments, a backside power delivery network (BSPDN) on a backside of the semiconductor device.

In some embodiments, the gate contact is partially etched into the first SAC dielectric cap and the second dielectric layer.

In some embodiments, the semiconductor device includes a metal track (M1 track) over the gate contact, and a via connecting the gate channel to the M1 track via the gate contact. The M1 track is a signal track.

In some embodiments, the gate contact is located at a negative field-effect transistor (NFET) to NFET cell boundary, or at a positive FET (PFET) to PFET cell boundary.

In some embodiments, the first SAC dielectric cap and the second SAC dielectric cap are made of SiN.

In some embodiments, the first dielectric layer is made of SiO2 and the second dielectric layer is made of SiN.

According to an embodiment, a method for fabrication of a semiconductor device includes forming a gate contact over a first gate channel of two adjacent gate channels, encapsulating a lower portion of a second dielectric layer by a first dielectric layer, covering a second side of the second dielectric layer by the first dielectric layer, and connecting the gate contact to an upper portion of the first side of the second dielectric layer. The first dielectric layer is extended vertically between two adjacent gate channels.

In some embodiments, the method further includes connecting the first dielectric layer to the second gate channel of the two adjacent gate channels.

In some embodiments, the method includes covering portions of a top surface of the second dielectric layer by the gate contact.

In some embodiments, the method includes forming a first self-aligned contact (SAC) dielectric cap over the first gate channel of the two adjacent gate channels, forming a second SAC dielectric cap over the second gate channel of the two adjacent gate channels, and connecting the gate contact to the first SAC dielectric cap.

In some embodiments, the method includes forming a backside power delivery network (BSPDN) on a backside of the semiconductor device.

In some embodiments, the method includes partially etched the gate contact into the first SAC dielectric cap and the second dielectric layer.

In some embodiments, the method includes forming a metal track (M1 track) over the gate contact and forming a via connecting the gate channel to the M1 track via the gate contact.

In some embodiments, the method includes forming the gate contact at a negative field-effect transistor (NFET) to NFET cell boundary, or at a positive FET (PFET) to PFET cell boundary.

According to an embodiment, a semiconductor device includes a dielectric structure between a first gate channel and a second gate channel, a gate contact over the first gate channel and covering an upper portion of the dielectric structure, and a first self-aligned contact (SAC) dielectric cap and a second SAC dielectric cap over the first and second gate channels, respectively. These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1C illustrate a semiconductor device, in accordance with some embodiments.

FIG. 1D depicts the side-view sections from which the semiconductor device is illustrated.

FIGS. 2A-2D illustrate a semiconductor device after formation of the source/drain regions, in accordance with some embodiments.

FIGS. 3A-3D illustrate a semiconductor device after the formation of the interlayer dielectric, in accordance with some embodiments.

FIGS. 4A-4D illustrate a semiconductor device after the removal of the dummy gates, in accordance with some embodiments.

FIGS. 5A-5D illustrate a semiconductor device after formation the recession of the metal gates, in accordance with some embodiments.

FIGS. 6A-6D illustrate a semiconductor device after formation of the self-aligned contact dielectric cap contact, in accordance with some embodiments.

FIGS. 7A-7D illustrate a semiconductor device after patterning the gate cuts, in accordance with some embodiments.

FIGS. 8A-8D illustrate a semiconductor device after the gate cut filling, in accordance with some embodiments.

FIGS. 9A-9D illustrate a semiconductor device after the formation of additional interlayer dielectric, in accordance with some embodiments.

FIGS. 10A-10D illustrate a semiconductor device after the patterning the source/drain contact, in accordance with some embodiments.

FIGS. 11A-11D illustrate a semiconductor device after pattering the gate contact, in accordance with some embodiments.

FIGS. 12A-12D illustrate a semiconductor device after removing portions of the self-aligned contact dielectric cap and the first dielectric layer, in accordance with some embodiments.

FIGS. 13A-13D illustrate a semiconductor device after the gate contact metallization and the source/drain contact metallization, in accordance with some embodiments.

FIGS. 14A-14D illustrate a semiconductor device after the formation of the via and the metal track, in accordance with some embodiments.

FIGS. 15A-15D illustrate a semiconductor device after the formation of the back end of line and the carrier wafer bonding, in accordance with some embodiments.

FIGS. 16A-16D illustrate a semiconductor device after the substrate removal, in accordance with some embodiments.

FIGS. 17A-17D illustrate a semiconductor device after removal of the etch stop layer, in accordance with some embodiments.

FIGS. 18A-18D illustrate a semiconductor device after the formation of the backside interlayer dielectric, in accordance with some embodiments.

FIGS. 19A-19D illustrate a semiconductor device after the formation of the backside contact and the backside power delivery network, in accordance with some embodiments.

FIG. 20 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

The concepts herein relate to routability in a semiconductor device. On a high level, the routability is an assessment of how easily and reliably the desired interconnections between transistors, standard cells and components can be physically realized on a chip to successfully fabricate an IC meeting performance requirements. Thus, improving routability translates to higher yield and reliability. Typically, the routability is affected by the number of available metal layers and tracks that can accommodate the required interconnect wires to connect transistors and components in an IC, as more metal layers improves routability. Transistor density and spacing requirements between transistors and widths of metal wires needed to connect transistors without shorts or reliability issues also impact the routability. Further, to enhance the routability, the ability to insert vias and contacts to connect two metal layers vertically in ICs without violating design rules for minimum widths and spaces should be improved. Even further, modularity and hierarchy in routing architecture surrounding transistors and logic blocks that allow reusable routing topologies can improves routability.

The positioning of gate contacts within an electronic circuit design plays a significant role in determining the ease with which electrical connections can be routed, as the flexibility granted in the placement of the gate contacts holds significant sway over the overall design's efficiency and functionality. When gate contacts are strategically positioned within the circuit layout, they simplify the task of connecting various components. Such a strategic placement can reduce the complexity of routing traces to reach the associated components, facilitating a more streamlined design process. Furthermore, the arrangement of gate contacts can help mitigate issues related to electromagnetic interference (EMI) and crosstalk between signals. By separating gate contacts for sensitive circuits and high-speed signals, designers can enhance signal integrity and minimize unwanted interference.

Optimizing signal paths is another advantage of strategic gate contact placement. By positioning gate contacts in a manner that ensures critical signals have shorter and more direct routes, designers can improve the overall performance of the circuit. Efficient gate contact placement can also lead to the optimal utilization of available space on a printed circuit board (PCB) or integrated circuit (IC). This, in turn, can contribute to reducing the overall size of the design while maintaining its functionality.

As an example, exclusively confining gate contact placement to the shallow trench isolation (STI) region within an electronic circuit design has a notable impact on the overall ease of routing connections, and it typically leads to suboptimal routability outcomes. When gate contacts are limited to the STI region, it introduces significant routing constraints. This limitation restricts the options available for routing traces and interconnections, often resulting in congested routing paths. As a consequence, establishing efficient connections between various components becomes challenging. Furthermore, concentrating gate contacts within the STI region tends to increase the EMI and crosstalk between adjacent signal, which can compromise signal quality and elevate the risk of signal integrity issues, negatively affecting the overall performance of the circuit. The decision to place gate contacts exclusively in the STI region can also lead to longer and less direct signal paths, due to the constraints imposed by this choice. Longer signal paths may introduce additional propagation delay and signal attenuation, particularly in high-speed circuit designs, which can further degrade performance. In terms of space utilization, relying solely on the STI region for gate contact placement may not make efficient use of the available space on the PCB or IC. Such an inefficiency can lead to wasted space and potentially limit the compactness of the design. However, positioning the gate contact at the edge of the gate channel can increase the risk of shorting the gate contact and the neighboring gate channel.

To tackle the above-mentioned and other problems, disclosed is a semiconductor device with gate contact at the edge of the gate channel which is isolated from the neighboring gate channels. This approach holds immense potential due to its remarkable synergy with the backside power delivery network (BSPDN). One advantage of the disclosed configuration lies in its transformative impact on the utilization of the metal tracks, particularly the metal layer 1 (M1) track, between cell boundaries. This strategic repurposing of resources allows for highly efficient signal routing within the circuit design.

This disclosure represents a departure from conventional design practices, which typically position the gate contacts within predetermined areas of the circuit layout, with little variation from established guidelines. The teachings herein provide a semiconductor device that introduces a paradigm shift by permitting gate contacts to span the edge of the gate channel, which fundamentally changes the way circuit layouts are approached and introduces several notable advantages. Foremost among these advantages is the seamless integration of this design concept with the BSPDN strategy. BSPDN serves as a critical component within integrated circuits, responsible for the efficient distribution of power throughout the circuit. By deliberately placing gate contacts along the edge of the gate channel, a harmonious alignment with the BSPDN strategy is achieved.

In an aspect, such an alignment unlocks a new avenue for the utilization of the metal tracks, specifically the M1 track, which traditionally acts as a conduit between cell boundaries. In traditional circuit design, the M1 track is primarily allocated for signal routing, a task that often presents challenges due to space constraints and the potential for interference. However, the ingenious placement of gate contacts along the gate channel's edge creates a dedicated pathway for signal routing along the M1 track. This dedicated routing corridor alleviates congestion issues and significantly reduces the risk of signal interference, such as noise and cross-talk, between adjacent traces. Consequently, signal routing within the circuit becomes not only more efficient but also substantially more reliable, enhancing the overall performance and functionality of the electronic design. By harnessing this design concept, the utilization of the M1 track for signal routing becomes optimized, offering improved efficiency, reliability, and reduced susceptibility to interference.

Accordingly, the teachings herein provide methods and systems of semiconductor device formation with gate contacts over the edge of the gate channels. The techniques described herein may be implemented in a number of ways. Example implementations are provided below with reference to the following figures.

### Example Semiconductor Device With Gate Contact Over The Edge of the Gate Channel Structure

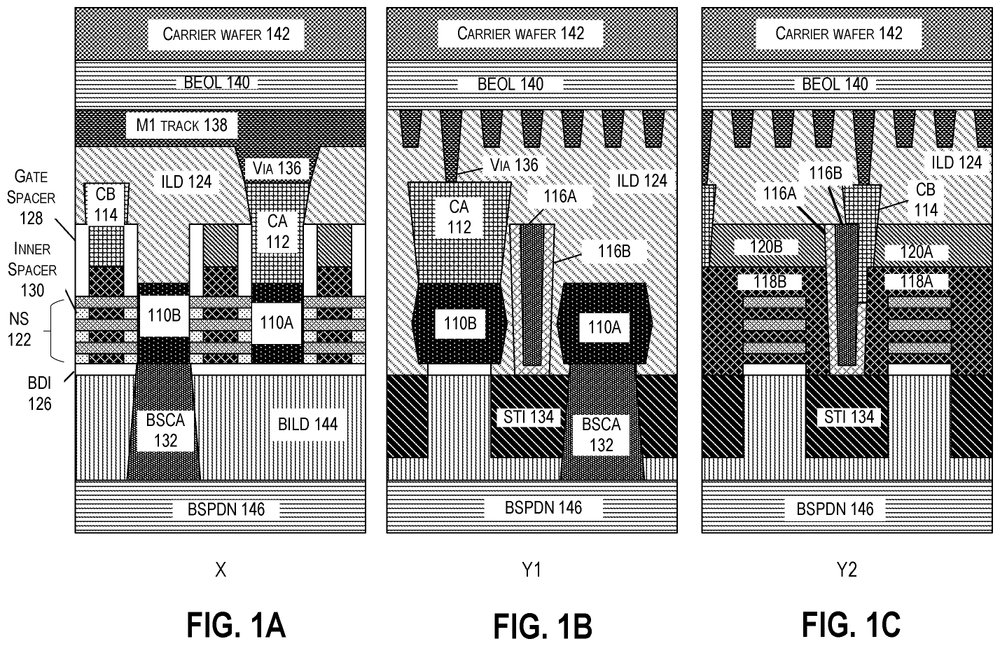

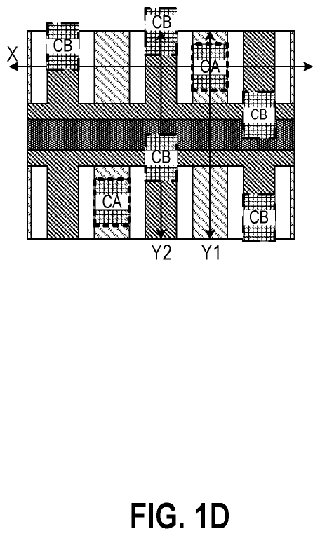

Reference now is made to FIGS. 1A-1C, which are simplified cross-section views of a semiconductor device across X-section, Y1-section and Y2-section, respectively, consistent with an illustrative embodiment. FIG. 1D illustrates each of the X-section, the Y1 section and the Y2-section in a top-down view. The disclosed semiconductor device can include a first source/drain region 110A, a second source/drain region 110B, a source/drain contact, CA 112, a gate contact, CB 114, a first dielectric layer 116A, a second dielectric layer 116B, a first gate channel 118A, a second gate channel 118B, a first self-aligned contact (SAC) dielectric cap 120A, a second SAC dielectric cap 120B, a plurality of nanosheets, NS 122, an interlayer dielectric, ILD 124, a dielectric layer, BDI 126, a gate spacer 128, an inner spacer 130, a backside contact, BSCA 132, a shallow trench isolation, STI 134, a via 136, a first metal layer, M1 track 138, a back end of line, BEOL 140, a carrier wafer 142, a bottom ILD, BILD 144, and a backside power delivery network, BSPDN 146.

Generally, the first source/drain region 110A and the second source/drain region 110B are two salient components that play relevant roles in the semiconductor device's operation. In various embodiments, the first source/drain region 110A and the second source/drain region 110B are regions within the semiconductor material, e.g., the semiconductor device, where the current flows in and out of the semiconductor device. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

The CA 112, located over the second source/drain region 110B, establishes a connection between the second source/drain region 110B and the BEOL 140, via the via 136 and the M1 track 138. The CA 112 ensures efficient electrical routing and connectivity within the semiconductor device. The fabrication of the CA 112 can involve lithography and etching processes to define the contact area. The CA 112 can be made using conductive materials such as copper (Cu) or tungsten (W).

The CB 114 is located over the edge of one of the gate channels, e.g., the first gate channel 118A. The CB 114 can be a gate electrode which applies electric field across the gate dielectric onto the gate channel underneath to dynamically control conductivity and switch the channel current on/off. In some embodiments, the CB 114 is made from polysilicon or a layered metallic stack and handles high frequencies. The CB can be connected to the edge of the gate channel and the SAC dielectric cap over the gate channel on one side, and the second dielectric layer 116B on the other side. Further, the lower portion of the CB 114 can be connected to the upper portion of the first dielectric layer 116A.

The CB 114 can be located at a negative field-effect transistor (NFET)-NFET cell boundary. Alternatively, the CB 114 can be located at a positive FET (PFET)-PFET cell boundary.

An NFET is a type of metal-oxide-semiconductor field-effect transistor (MOSFET) that uses an n-type semiconductor for the channel between the source and drain terminals. An NFET conducts current via negative charge carriers or electrons flowing from the source to the drain when a positive voltage is applied at the gate terminal with respect to the grounded source. The NFET cell boundary can include the layout dimension restrictions defined around each individual NFET transistor, setting spacing rules and scaling dimensions for that component on a semiconductor die or chip. In some embodiments, the cell boundary for an NFET would encompass the entire area allocation needed for that transistor's source/drain regions diffusions/implants along with interconnect cutouts for contacts, active transistor channel region under the gate, and surrounding isolation spacing from other adjacent devices.

Similarly, PFETs use p-type semiconductor material for the channel between source and drain regions, unlike n-type channel material in NFETs. Current flows through the PFET channel using positive charge carriers or holes when a negative voltage is applied to the PFET's gate terminal. PFETs operate complementary to NFETs; PFETs turn on and pass current with negative gate voltages, while NFETs require positive gate voltages to turn on. PFETs and NFETs can be used together to take advantage of low power rail-to-rail switching enabled by alternating conductive states.

The first dielectric layer 116A is extended vertically between the first gate channel 118A and the second gate channel 118B. In some embodiments, the first dielectric layer 116A can be made of SiN. The first dielectric layer 116A is recessed so that the second dielectric layer 116B is formed within the recess. In some embodiments, the lower portions of the first dielectric layer 116A cover the upper surface of the STI 134, thus, the second dielectric layer 116B has no direct contact with the STI 134. Further, the sidewalls of the first dielectric layer 116A are in contact with two adjacent source/drain regions, e.g., the first source/drain region 110A and the second source/drain region 110B, as shown in FIG. 1B. The sidewalls of the first dielectric layer 116A are in contact with two adjacent gate channels, e.g., the first gate channel 118A and the second gate channel 118B, as shown in FIG. 1C. As shown in FIG. 1C, the upper portions of the sidewalls of the first dielectric layer 116A on one side are removed and are covered by the CA 112.

The second dielectric layer 116B is extended vertically within the first dielectric layer 116A. In some embodiments, the second dielectric layer 116B can be made of SiO2. In other words, the first dielectric layer 116A encapsulates the lower portions of the second dielectric layer 116B. While the second dielectric layer 116B is vertically extended to a first heigh above the gate channels on both sides, only one side of the first dielectric layer 116A is vertically extended to first height. That is, the first dielectric layer 116A and the second dielectric layer 116B are coplanar. As mentioned above, the upper portions of the first dielectric layer 116A are removed on one side and are replaced by the CB 114.

In various embodiments, the first gate channel 118A and the second gate channel 118B serve as control elements that regulate the flow of current through the semiconductor device. The first gate channel 118A and the second gate channel 118B can be composed of a conductive material. The first gate channel 118A and the second gate channel 118B can control the flow of electric current between the source and drain regions. In some embodiments, by applying a voltage to the gate, the channel region's conductivity is modulated, allowing the semiconductor device to either allow or block the flow of current, which in turn enables the semiconductor device to act as electronic switches or amplifiers. The gate voltage can determine whether the semiconductor device is in an “on” or “off” state. When the gate voltage is below a certain threshold, the semiconductor device is in the “off” state, and the current flow between the source and drain is effectively blocked. On the other hand, when the gate voltage exceeds the threshold, the semiconductor device enters the “on” state, allowing current to flow through the channel region. In addition to acting as a switch, modulating the gate voltage can enable the first gate channel 118A and/or the second gate channel 118B to control the current flowing through the channel region, resulting in amplified output signals.

In an embodiment, the first gate channel 118A and the second gate channel 118B can enable the implementation of Boolean logic operations, such as AND, OR, and NOT, by controlling the flow of current based on the input voltages. Multiple semiconductor devices can be interconnected to form complex logic circuits, enabling the execution of various computational tasks in digital systems. In some embodiments, the first gate channel 118A and the second gate channel 118B, along with other semiconductor device components, can facilitate the miniaturization and integration of electronic circuits. The ability to control the channel region's conductivity through the gate voltage allows for compact and highly efficient circuit designs.

The first SAC dielectric cap 120A can be a thin insulating layer or material placed on top of the first gate channel 118A, serving as a protective and performance-enhancing component, to prevent unintended electrical contact or leakage between the first gate channel 118A and nearby components, e.g., the first source/drain region 110A, ensuring proper operation and avoiding electrical short circuits.

The first SAC dielectric cap 120A can act as a charge barrier to prevent the loss or diffusion of electric charge from the first gate channel 118A. In an embodiment, the first SAC dielectric cap 120A can serve as a protective layer for the underlying gate oxide, which is a thin insulating layer between the first gate channel 118A and the channel region. By covering the gate oxide with the first SAC dielectric cap 120A, the gate oxide is shielded from physical damage, contamination, or chemical reactions that could degrade its electrical properties. In some embodiments, the first SAC dielectric cap 120A can be used to control and manage the mechanical stress in the semiconductor device structure. In several embodiments, the first SAC dielectric cap 120A serves as a surface passivation layer, protecting the semiconductor device's surface from contamination, oxidation, or other environmental effects.

The second SAC dielectric cap 120B can be a thin insulating layer or material placed on top of the second gate channel 118B, serving as a protective and performance-enhancing component, to prevent unintended electrical contact or leakage between the second gate channel 118B and nearby components, e.g., the second source/drain region 110B, ensuring proper operation and avoiding electrical short circuits. The second SAC dielectric cap 120B can act as a charge barrier to prevent the loss or diffusion of electric charge from the second gate channel 118B. In an embodiment, the second SAC dielectric cap 120B can serve as a protective layer for the underlying gate oxide, which is a thin insulating layer between the second gate channel 118B and the channel region. By covering the gate oxide with the second SAC dielectric cap 120B, the gate oxide is shielded from physical damage, contamination, or chemical reactions that could degrade its electrical properties. In some embodiments, the second SAC dielectric cap 120B can be used to control and manage the mechanical stress in the semiconductor device structure. In several embodiments, the second SAC dielectric cap 120B serves as a surface passivation layer, protecting the semiconductor device's surface from contamination, oxidation, or other environmental effects. The first SAC dielectric cap 120A and the second SAC dielectric cap 120B can be made of SiN.

In some embodiments, the first dielectric layer 116A, the second dielectric layer 116B, the first SAC dielectric cap 120A and the second SAC dielectric cap 120B are so vertically extended that the top surface of the first dielectric layer 116A which is not covered by the CB 114, the top surface of the second dielectric layer 116B, the top surface of the first SAC dielectric cap 120A, and a top surface of the second SAC dielectric cap 120B are coplanar. As shown in FIG. 1C, in some embodiments, the CB 114 is partially etched into the first SAC dielectric cap 120A and the first dielectric layer 116A.

The NS 122 can be alternating, vertically-oriented sheets, which can drive current in a small footprint area. In some embodiments, NS 122 includes silicon nanowires. In other words, NS 122 includes three-dimensional structures in the gate channel, which are extended from a source region towards a drain region.

The ILD 124 can be a layer of insulating material to electrically isolate and provide mechanical support between different layers of conducting and active components. The ILD 124 can enable efficient signal transmission, reduce crosstalk, and ensure the proper functioning of the semiconductor device. In an embodiment, the ILD 124 can electrically isolate adjacent conducting layers or active components in the semiconductor device. By providing insulation between different layers, the ILD 124 can prevent electrical shorts, reduce (e.g., minimize) leakage current, and ensure that signals are directed only along the desired pathways. In some embodiments, the ILD 124 can help reduce parasitic capacitance between adjacent metal interconnects or active devices and provide mechanical support to the semiconductor device's structure.

The BDI 126 can electrically isolate individual components in the semiconductor device, and provide electrical isolation between the components. That is, the BDI 126 can ensure that the operation of one component does not interfere with the operation of the others. By using a dielectric layer, which is an insulating layer that does not conduct electricity, the BDI 126 effectively prevents electrical crosstalk between the transistors and allows each one to operate independently. Further, by electrically isolating each transistor from the other, the BDI 126 can reduce the potential for crosstalk, which is the unwanted transfer of signals between circuit elements, thereby improving the overall performance of the semiconductor device.

By isolating each transistor, BDI 126 helps to prevent the failure of one transistor from affecting the others. This can improve the overall reliability of the device. Additionally, the BDI 126 allows for more flexibility in device design, as it allows each transistor in the stack to be accessed and controlled independently. This can be beneficial in a variety of applications where specific transistors may need to be activated or deactivated based on certain conditions. In some embodiments, the BDI 126 can help decrease the parasitic capacitance associated with the transistor, which can lead to faster switching times and improved performance.

The gate spacer 128 is an insulating material layer that surrounds and isolates the gate electrode of the semiconductor device. The gate spacer 128 electrically isolates the gate channel from a source/drain region to prevent unwanted electrical leakage. In some embodiments, the gate spacer 128 can help define the length of the gate channel beneath the gate electrode. In some embodiments, the gate spacer 128 is made of silicon dioxide (SiO2), silicon nitride (Si3N4), or a high-k dielectric.

The inner spacer 130 is an insulating material layer that isolates the nanosheets of the semiconductor device. The inner spacer 130 electrically isolates the individual nanosheets from each other to prevent unwanted electrical leakage. In some embodiments, the gate spacer 128 is made of silicon dioxide (SiO2), silicon nitride (Si3N4), or a high-k dielectric.

The BSCA 132 is a region on the backside of the semiconductor device where electrical connections are made. By establishing the electrical contacts, the BSCA 132 ensures the proper functioning of the semiconductor device and facilitates electrical signal transmission.

The BSCA 132 can serve as a thermal interface between the semiconductor device and a heat sink or other cooling mechanisms. By establishing direct contact with the substrate, the BSCA 132 can conduct the heat away from the semiconductor device, and contribute to improved thermal dissipation. In some embodiments, the BSCA 132 can help mitigate parasitic effects, such as substrate coupling or substrate noise, from the semiconductor device. In further embodiments, the BSCA 132 can allow for increased integration density in the semiconductor device. In an embodiment, the BSCA 132 can serve as a means of providing electrostatic discharge (ESD) protection to the semiconductor device. ESD events can cause significant damage to sensitive electronic components and thus should be avoided.

The via 136 establishes a vertical electrical connection between the second source/drain region 110B and the BEOL 140 through the CA 112. The via 136 can facilitate efficient power delivery and signal transmission between the second source/drain region 110B and the BEOL 140. Fabrication of the via 136 involves a series of processes, including lithography, etching, and deposition. The via 136 can be formed using conductive materials such as copper (Cu) or tungsten (W). The presence of the via 136 enables improved (e.g., optimal) electrical connectivity, contributing to improved device performance and reduced power losses.

In some embodiment, the M1 track 138 can be used to connect various elements of the semiconductor device to the BEOL 140. The STI 134 helps prevent electrical crosstalk and interference between adjacent components, allowing for the proper functioning of integrated circuits. The M1 track 138 can be a signal track, which is a conductive metal interconnect path used to route electrical signals into and out of the semiconductor device's terminals. In some embodiments, the M1 track 138 are patterned from aluminum, copper or other conductive layers separated by insulating dielectric films. The M1 track wires can specifically route signals between the source/drain regions, and gate terminals to logic components, input/output ports or power supplies.

The BILD 144 can be an insulating material or layer used to isolate and provide electrical insulation between the semiconductor device's active regions and the BSCA 132, and to prevent unwanted electrical contact between the active regions and the backside contact, ensuring the proper functioning and integrity of the semiconductor device. In various embodiments, the BILD 144 can act as a protective layer, shielding the active regions of the semiconductor device from external contaminants, moisture, and mechanical stress. The BILD 144 can further help prevent physical damage, such as scratches or particle contamination, which could adversely affect semiconductor device performance. Additionally, the BILD 144 can act as a barrier against moisture ingress, which can cause corrosion and degradation of the semiconductor device's components.

In several embodiments, the BILD 144 can provide structural support to the semiconductor device by maintaining the mechanical integrity and stability of the semiconductor device. The BILD 144 can further help prevent the warping, bending, or cracking of the substrate, particularly during the manufacturing process or subsequent handling. The BILD 144 can ensure that the semiconductor device remains mechanically robust and maintains its dimensional stability.

In an embodiment, the BILD 144 can also serve as a planarization layer in the semiconductor device fabrication process. As various layers are deposited and patterned on the front side of the semiconductor device, irregularities or topographic variations may arise. The BILD 144 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 144 can contribute to improved overall semiconductor device performance. In several embodiments, BILD 144 can facilitate wafer-level testing of the semiconductor device. By providing electrical isolation between the active regions and the backside contact, individual semiconductor device or elements on the semiconductor device can be electrically accessed and tested without interference from neighboring devices or components. This enables efficient and accurate wafer-level testing, ensuring quality control during semiconductor manufacturing.

Example Fabrication Acts Of Semiconductor Device with Gate Contact Over Edge of Gate Channel

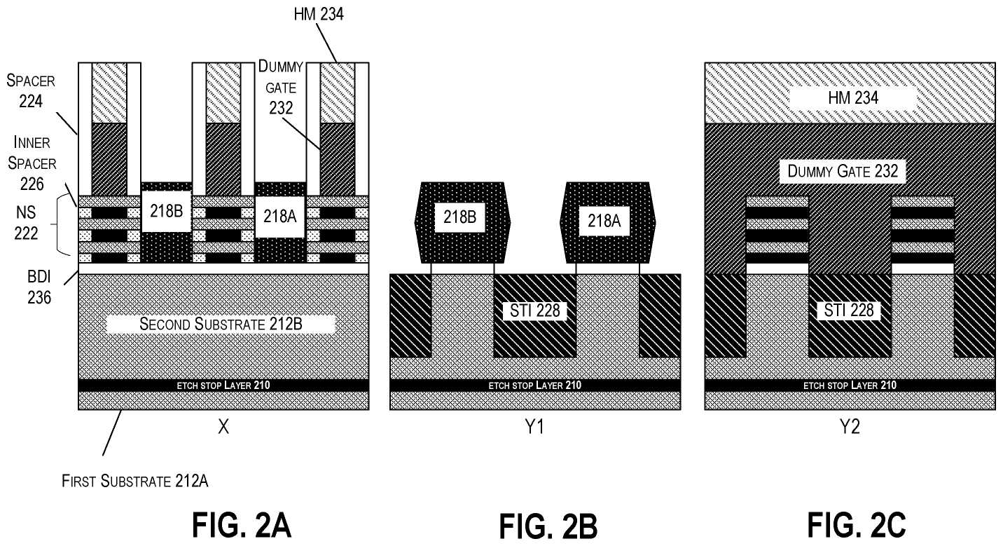

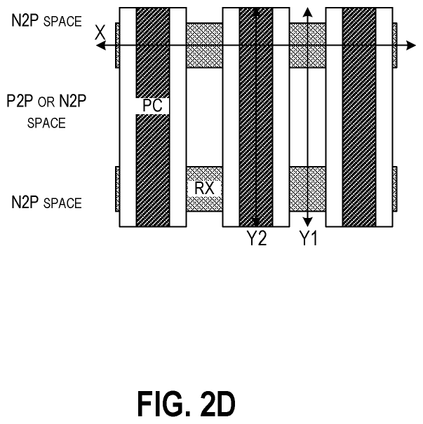

With the foregoing description of an example semiconductor device, it may be helpful to discuss an example process of manufacturing the same. To that end, FIGS. 2-19 illustrate various acts in the manufacture of a semiconductor device, consistent with illustrative embodiments. Figures denoted by A, B and C illustrate an act of fabrication of the semiconductor device from a different point of view across the X-section, the Y1-section, and the Y2-section, respectively, consistent with an illustrative embodiment. Figures denoted by D illustrate a top-down view of the semiconductor device.

Reference now is made to FIGS. 2A-2C, which are simplified cross-section views of a semiconductor device, after formation of the source/drain regions, consistent with an illustrative embodiment. FIG. 2D illustrates a top view of the semiconductor device after the formation of the source/drain regions. Once the source/drain regions are formed, the semiconductor device can include an etch stop layer 210 between a first substrate 212A and a second substrate 212B, a first source/drain region 218A, a second source/drain region 218B, nanosheets gates, NS 222, spacers 224, inner spacer 226, STI 228, dummy gate 232, a hard mask, HM 234, and BDI 236.

In the illustrative example depicted in FIGS. 2A-2C, the semiconductor device is depicted as being on silicon as the first substrate 212A and the second substrate 212B, while it will be understood that other types as substrates may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 212A and the second substrate 212B may include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, an etch stop layer 210 is formed over the first substrate 212A. The etch stop layer 210 can be a thin layer of material incorporated into the structure of the semiconductor device to provide a selective barrier against etching processes, preventing further removal of underlying materials during fabrication. The etch stop layer 210 can enable precise control over the etching depth and help define the desired device dimensions. The etch stop layer 210 can further provide a stopping point for the etching process, ensuring that specific layers or regions are not etched beyond a certain point, leading to accurate patterning and control of critical features. The etch stop layer 210 can create a distinct separation between different layers or components within the device structure, and prevent the undesired etching of underlying layers or materials, enabling the creation of complex, multi-layered structures with well-defined interfaces and boundaries. In some embodiments, the etch stop layer 210 acts as a protective barrier for sensitive or delicate materials to shield such materials from aggressive etchants, preventing damage or degradation during subsequent fabrication steps.

In some embodiments, prior to forming the etch stop layer 210, the first substrate 212A is prepared by cleaning and removing any impurities or oxide layers. The etch stop layer 210 is deposited onto the first substrate 212A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 210 can then be selectively etched, stopping at a predetermined depth, while protecting the underlying layers. After the etching process, the remaining photoresist can be removed through stripping techniques. While in some embodiments, SiGe is used to form the etch stop layer 210, in some embodiments, silicon nitride (SiN) or silicon oxynitride (SiON) can be used as the etch stop layer 210. In some embodiments, a second substrate layer 210b is epitaxially grown over the etch stop layer 210. A high-Ge SiGe layer can cover portions of the second substrate 212B. The high-Ge SiGe layer can isolate the second substrate 212B from the first source/drain region 218A, the second source/drain region 218B, and the NS 222. As shown in FIGS. 2B and 2C, the STI 228 can be formed within the second substrate 212B between the source/drain regions and the between the adjacent stacks of the NS 222.

In some embodiments, the NS 222 can be formed by alternating layers of Si layers 214A and SiGe layers 214B, in which sidewalls of the SiGe layers 214B are indented and covered by the inner spacer 226. The SiGe layers 214B can subsequently be removed and replaced with gate region materials.

The spacers 224 can be thin insulating layers or materials placed on the sidewalls of the gate regions, the dummy gate 232 and the HM 234. Th spacers 224 can help control the effective channel length of the semiconductor device. In an embodiment, the spacers 224 can allow for control over the channel's conductive properties, including resistance and carrier mobility, which can contribute to improved performance of the semiconductor device. The spacers 224 can be a low-k material.

In some embodiments, the spacers 224 can act as insulating layers between the gate regions and the first source/drain region 218A and the second source/drain region 218B. That is, the spacers 224 can help prevent current leakage or short circuits between the gate regions and the first source/drain region 218A and the second source/drain region 218B. Such isolation can help maintain the integrity of the semiconductor device's electrical operation and prevent unintended current flow that could negatively impact the performance of the semiconductor device and reliability.

In further embodiments, the spacers 224 can be utilized to modulate the overlapping capacitance between the gate regions and the first source/drain region 218A and the second source/drain region 218B. Overlapping capacitance can affect the semiconductor device's electrical characteristics, such as threshold voltage and switching behavior. Thus, by adjusting the thickness and material properties of the spacers 224, the overlapping capacitance can be optimized, which can allow for better control and modulation of the semiconductor device's behavior. In several embodiments, the spacers 224 can help mitigate the short-channel effects by physically separating the gate regions from the first source/drain region 218A and the second source/drain region 218B. To that end, the spacers 224 can create a barrier that restricts the extension of the electric field into the channel region, reducing the impact of drain-induced barrier lowering and subthreshold leakage. This mitigation can improve the semiconductor device's performance, reduce power consumption, and enhance overall device reliability.

In an embodiment, the spacers 224 can serve as barriers that prevent the lateral diffusion of dopant atoms from the first source/drain region 218A and the second source/drain region 218B, into the channel region during the doping process. Such diffusion can alter the channel characteristics and compromise the semiconductor device's performance. By confining the dopant diffusion, the spacers 224 can contribute to maintaining the desired semiconductor device's characteristics and electrical behavior. In some embodiments, the spacers 224 can be formed over the sidewalls of the gate regions. The spacers 224 can be formed by deposition techniques. Alternatively, the spacers 224 can be formed by etching or selectively epitaxially growing the spacers 224 over the sidewalls of the gate regions. In various embodiments, the spacers 224 can include SiGe.

In an embodiment, the inner spacer 226, similar to the spacers 224, can act as insulating layers between the gate regions and the first source/drain region 218A and the second source/drain region 218B. In various embodiments, the inner spacer 226 can be the same as the spacers 224, which are formed over portions of the gate regions confined between the nanosheet gates, NS 222.

The dummy gate 232 is a temporary disposable gate structure used in replacement metal gate transistor fabrication, that enables proper source/drain formation aligned to a gate structure before the final metal gate is integrated. In some embodiments, the dummy gate 232 includes deposited polysilicon and oxide layers. The HM 234 can be a non-photosensitive protective masking material that includes durable materials such as silicon dioxide or silicon nitride.

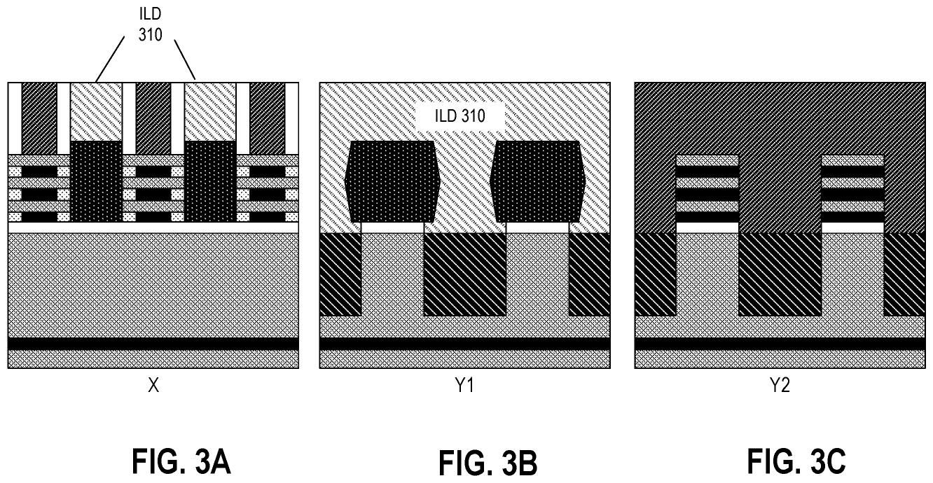

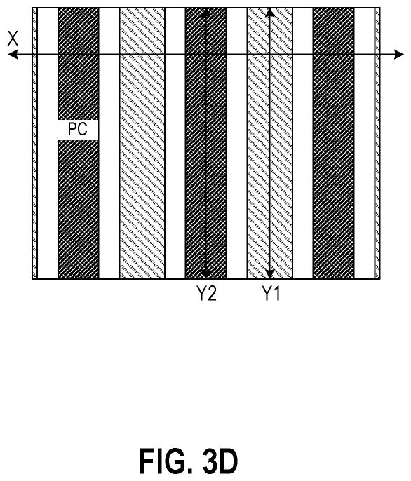

FIGS. 3A-3D illustrate a semiconductor device after the deposition of the interlayer dielectric, in accordance with some embodiments. In some embodiments, an interlayer dielectric, ILD 310, is formed over the semiconductor device, followed by the removal of the HM. In some embodiments, the HM is patterned using a lithographic technique by transferring the mask design into the hard mask layer before removing resist. The HM shields the underlying layers during subsequent etching steps due to its thinner robust nature compared to resist. After the etching, the HM pattern transfer is complete and the HM may be removed, or sometimes part of the mask is retained. The HM is a non-photosensitive protective masking material that includes durable materials such as silicon dioxide or silicon nitride. In some embodiments, the HM is patterned using a lithographic technique by transferring the mask design into the HM layer before removing resist.

In some embodiments, the HM is removed by a reactive ion etching (RIE) technique. Generally, RIE is a dry etching process used in semiconductor device fabrication to remove materials from the surface of a substrate selectively. In some embodiments, RIE can involve the use of reactive ions and plasma to react with and remove specific materials chemically. In an embodiment, the RIE process begins by placing the semiconductor device inside a vacuum chamber. The chamber is then evacuated to create a low-pressure environment. Reactive gases, which can include a combination of a chemically reactive gas and an inert gas, are introduced into the chamber. The chemically reactive gas, such as fluorine-based gases (e.g., CF4, SF6) or chlorine-based gases (e.g., Cl2), can react with the material to be etched, i.e., the second substrate, Si, while the inert gas, e.g., argon, can help to control the ion bombardment.

In some embodiments, Radiofrequency or microwave power is applied to create a plasma within the chamber. In such embodiments, power excites the gas molecules, causing them to ionize and form a plasma of reactive ions and electrons. The plasma can include reactive ions that chemically react with the silicon. The reactive ions bombard the substrate surface, break chemical bonds and remove silicon. In various embodiments, the RIE process can be selective, meaning it can mainly affect the target material, i.e., silicon, while leaving other materials, such as masking layers or underlying layers, relatively unaffected.

In some embodiments, to achieve selective etching, an etch mask can be applied on the substrate surface prior to the RIE process. The etch mask protects certain regions from etching, allowing the reactive ions to remove the exposed material selectively. The etching process can be controlled to achieve specific etch profiles, such as vertical sidewalls or tapered structures. Parameters such as gas composition, pressure, power, and process duration are adjusted to achieve the desired etch characteristics. In some embodiments, endpoint detection techniques, such as optical emission spectroscopy or laser interferometry, can be used to determine when the etching process has reached a desired endpoint. This ensures accurate control of the etch depth and prevents over-etching. After the etching process is completed, the substrate can be cleaned to remove any residue or by-products from the etching. Cleaning can involve rinsing with solvents or plasma cleaning to ensure the substrate's surface is free from contaminants.

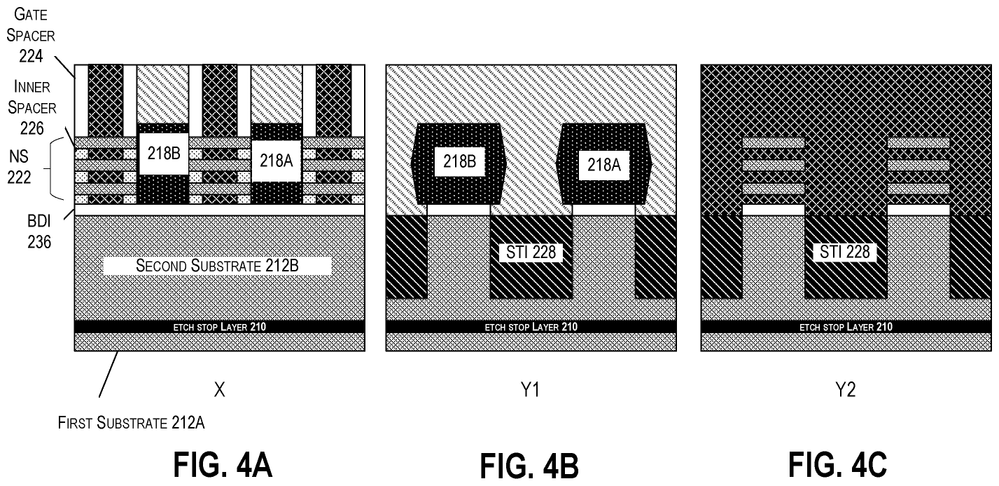

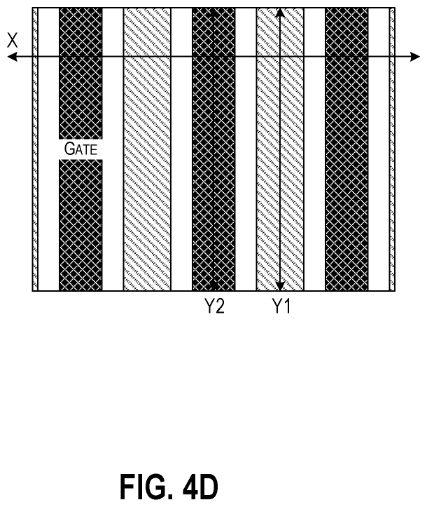

FIGS. 4A-4D illustrate a semiconductor device after the removal of the dummy gate, in accordance with some embodiments. In some embodiments, the dummy gate is removed by an RIE technique. The SiGe layers of the NS are removed and a gate regions are filled with a suitable material. The gate regions can be filled with a high-k material.

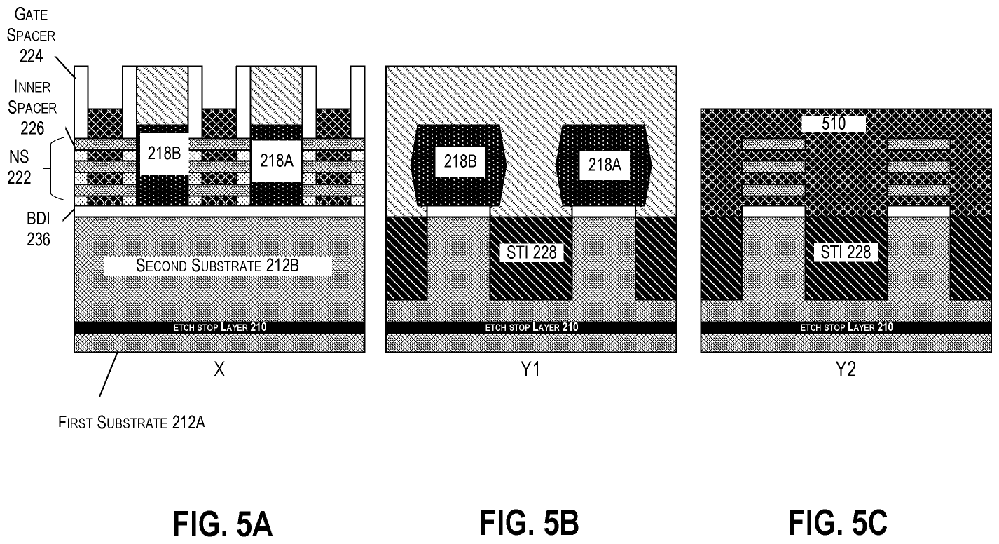

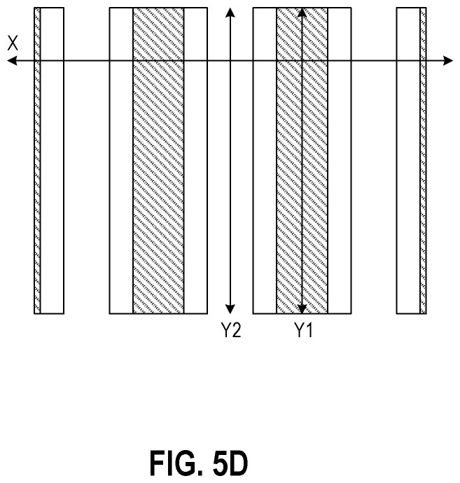

FIGS. 5A-5D illustrate a semiconductor device after the formation of the recession of the metal gates, in accordance with some embodiments. In some embodiments, portions of the high-k material are removed from the semiconductor device, which can form recesses over the gate channels 510.

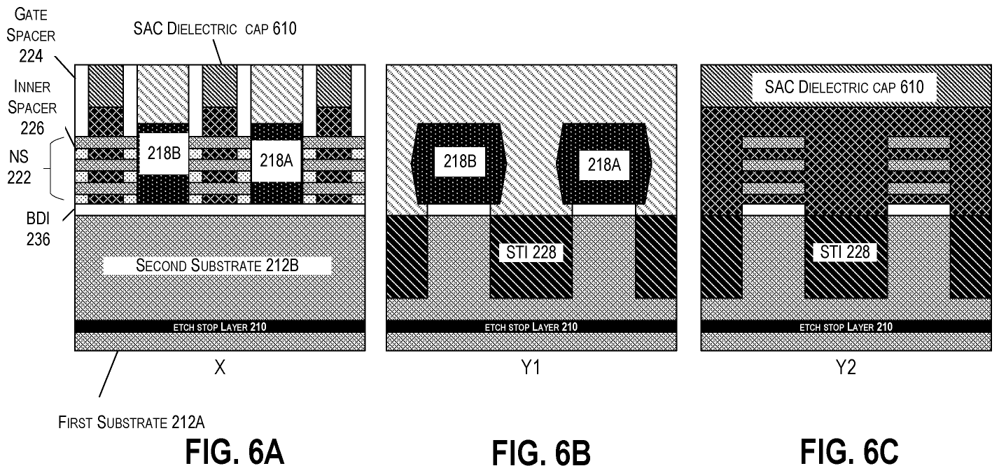

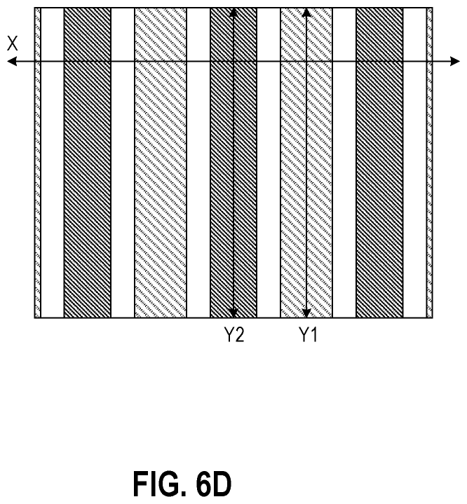

FIGS. 6A-6D illustrate a semiconductor device after the formation of the self-aligned contact dielectric cap, in accordance with some embodiments. In some embodiments, the SAC dielectric cap is formed over the high-k material used to fill the gate channels. As a result, the SAC dielectric cap 610 is formed over the gate channels. A chemical-mechanical polishing (CMP) process can be performed afterwards to clean the surface of the semiconductor device from the contaminations.

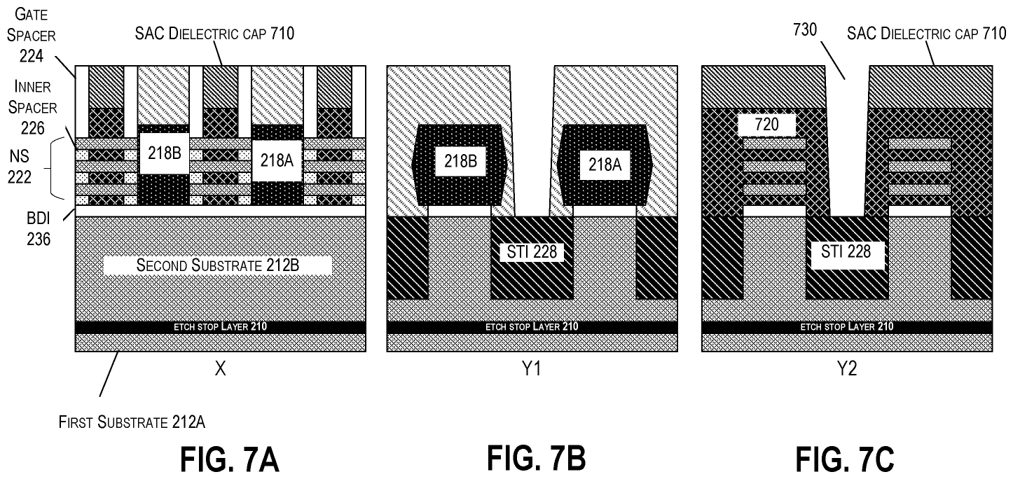

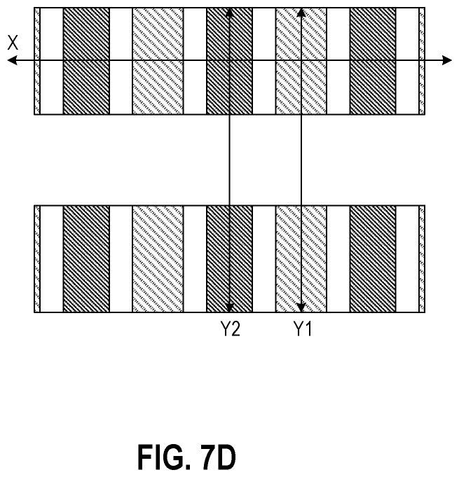

FIGS. 7A-7D illustrate a semiconductor device after patterning the gate cut, in accordance with some embodiments. In some embodiments, the SAC dielectric cap 710 and the high-k material are patterned by removing portions of the SAC dielectric cap 710 and the high-k material 720 to form a recess 730. The SAC dielectric cap/high-k material patterning is stopped at the STI 740.

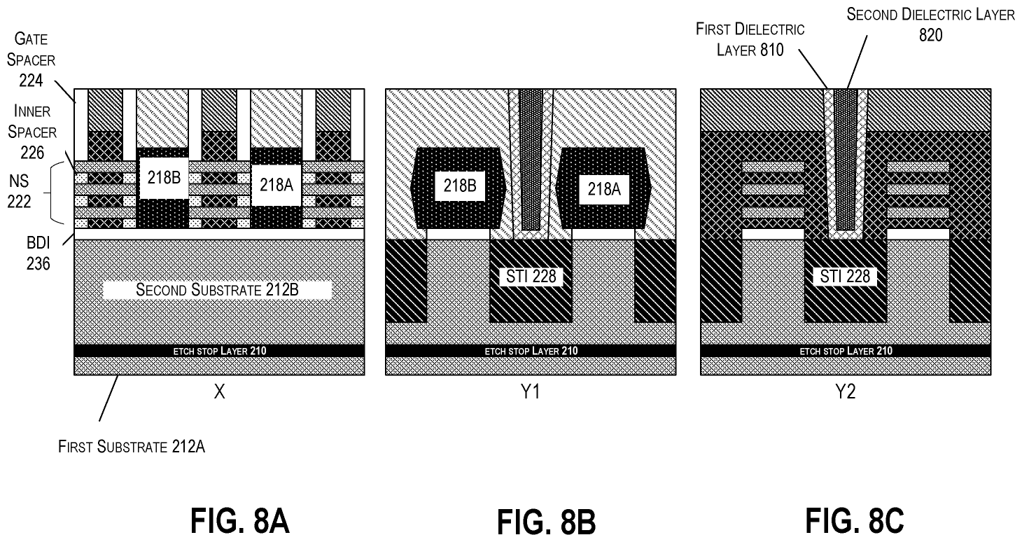

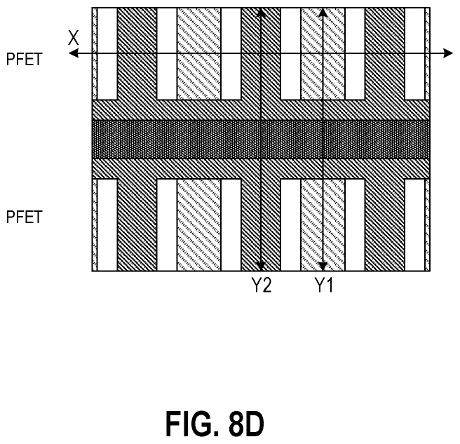

FIGS. 8A-8D illustrate a semiconductor device after the gate cut filling, in accordance with some embodiments. In some embodiments, the first dielectric layer 810 is formed over the bottom surface and the sidewalls of the recess, followed by the second dielectric layer 820 filling the remaining portions of the recess. As a result, a bilayer dielectric structure is formed which includes the first dielectric layer 810 as the liner, and the second dielectric layer 820 as the fill material.

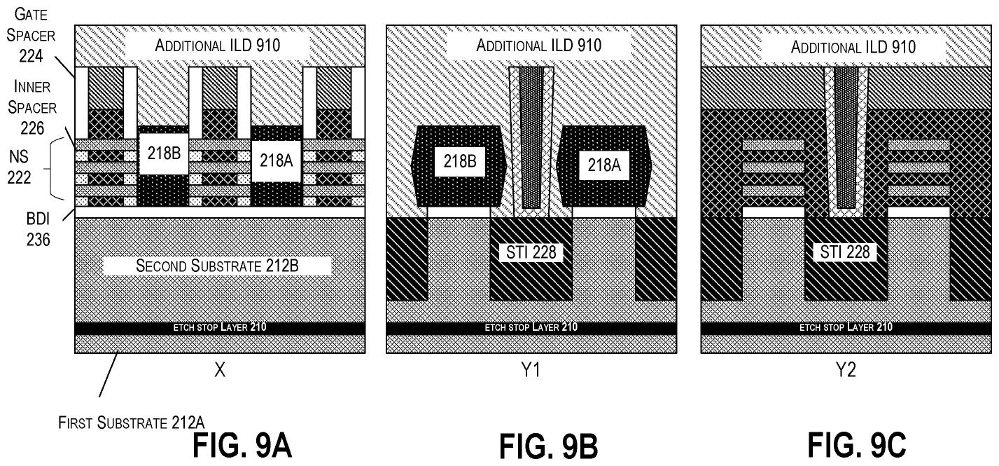

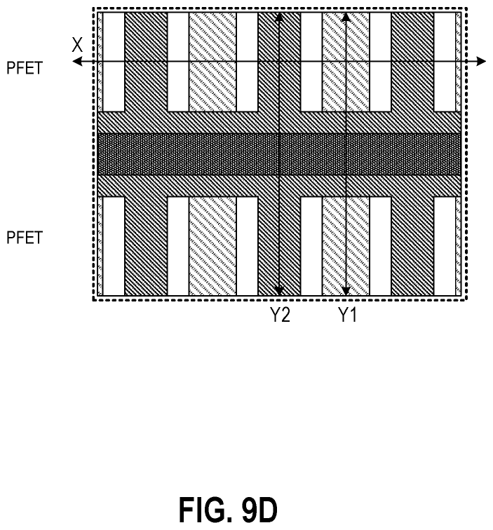

FIGS. 9A-9D illustrate a semiconductor device after the formation of additional interlayer dielectric, in accordance with some embodiments. In some embodiments, additional ILD 910 is formed over the semiconductor device, so the SAC dielectric cap, the first dielectric layer and the second dielectric layer are not exposed.

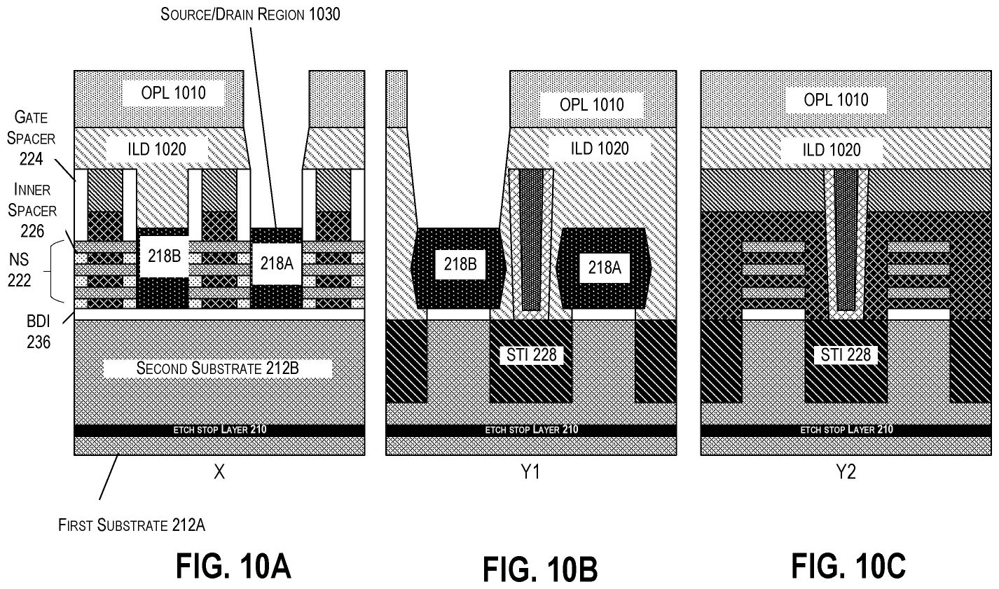

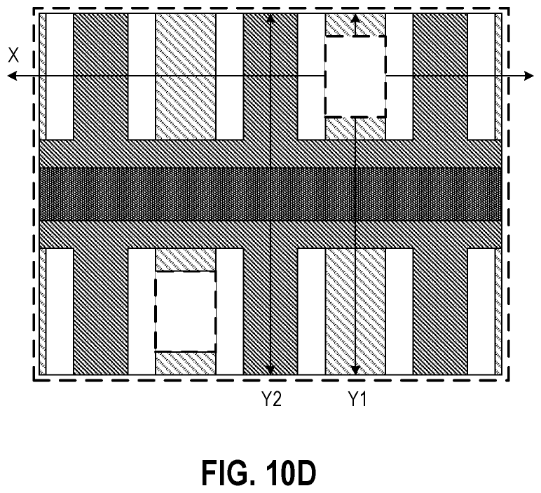

FIGS. 10A-10D illustrate a semiconductor device after the patterning the self-aligned source/drain contact, in accordance with some embodiments. In some embodiments, an organic planarization layer, OPL 1010 is formed over the semiconductor device. The OPL 1010 can include a photo-sensitive organic polymer having a light-sensitive material that, when exposed to electromagnetic (EM) radiation, is chemically altered and thus configured to be removed using a developing solvent. For example, in some embodiments, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene (BCB). In some embodiments, the OPL 1010 can include any organic polymer and a photoactive compound having a molecular structure that can attach to the molecular structure of the organic polymer. In some embodiments, the OPL 1010 material is selected to be compatible with an overlying antireflective coating (not shown) and/or an overlying photoresist (not shown). In some embodiments, the OPL 1010 can be applied using spin coating technology, although other techniques are within the contemplated scope of the present disclosure. The contact patterning is performed by removing portions of the OPL 1010 and the ILD 1020 to expose a source/drain region 1030.

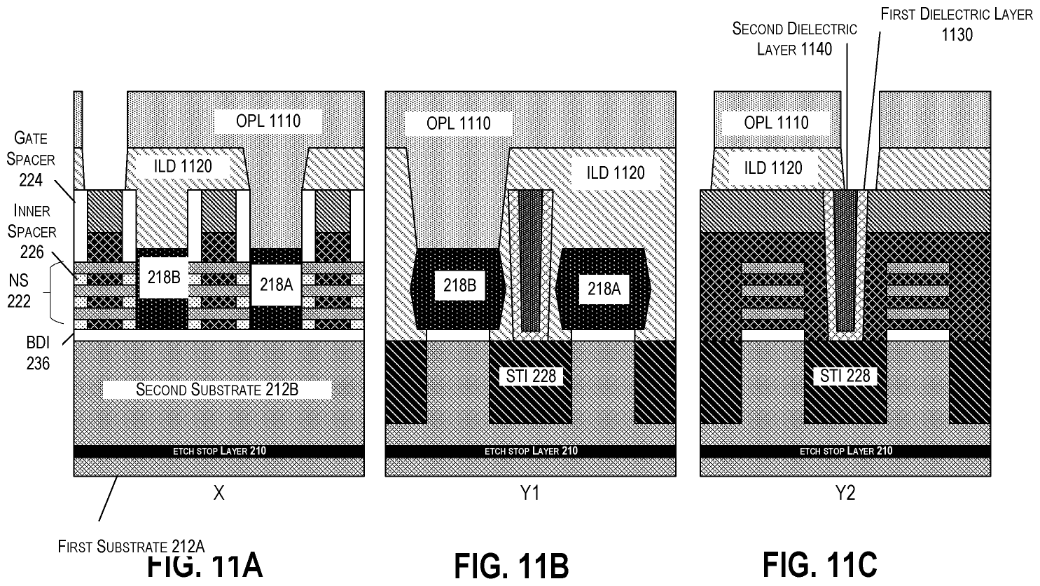

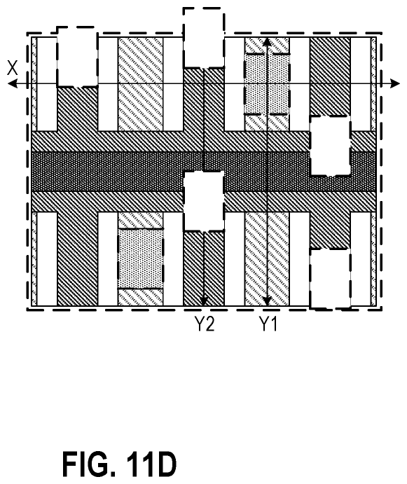

FIGS. 11A-11D illustrate a semiconductor device after the patterning the gate contact, in accordance with some embodiments. In some embodiments, the OPL ashing is performed to create a flat surface for subsequent lithography and deposition steps. Thus, the semiconductor device's surface is covered by the OPL 1110. Subsequently, the gate contact patterning is performed by recessing portions of the OPL 1110 and the ILD 1120 over a gate region. In some embodiments, the recession is performed so that portions of the first dielectric layer 1130, the second dielectric layer 1140, the SAC dielectric cap 1150, and the edge of the first gate channel are exposed.

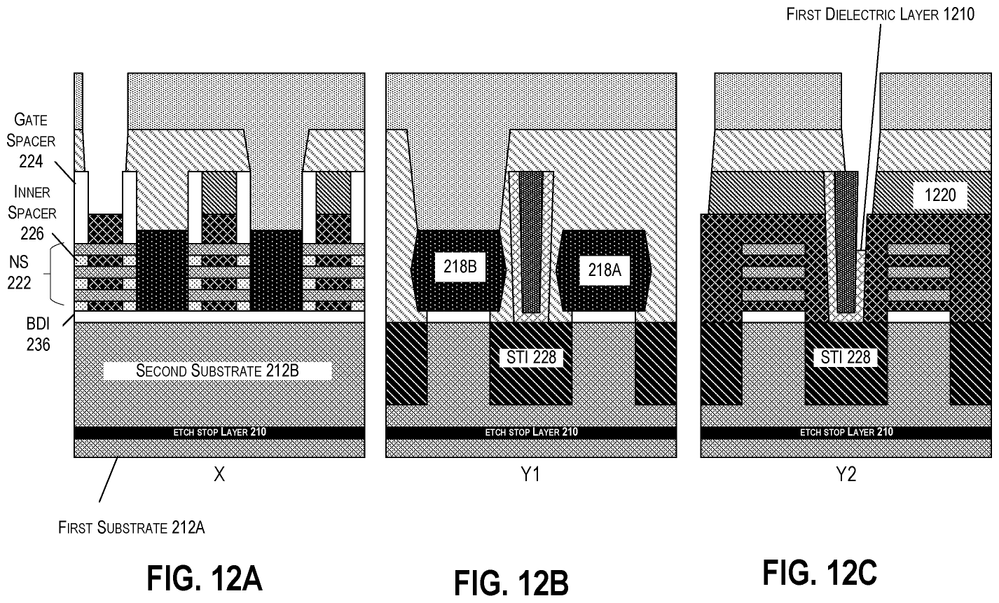

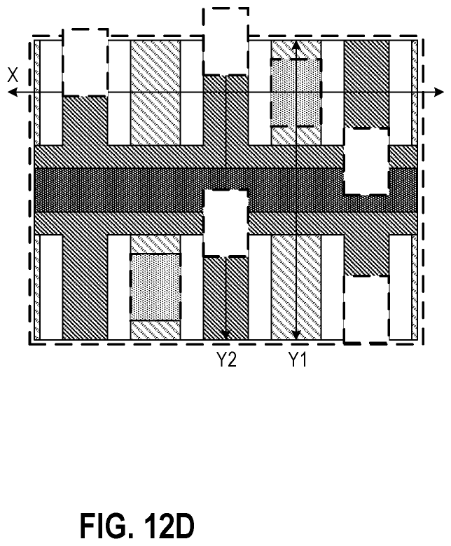

FIGS. 12A-12D illustrate a semiconductor device after removing portions of the self-aligned contact dielectric cap and the first dielectric layer, in accordance with some embodiments. In some embodiments, portions of the first dielectric layer 1210 and portions of the SAC dielectric cap 1220 are removed and the high-k material of the gate channel is exposed. In some embodiments, the removal process is performed by a selective etching technique.

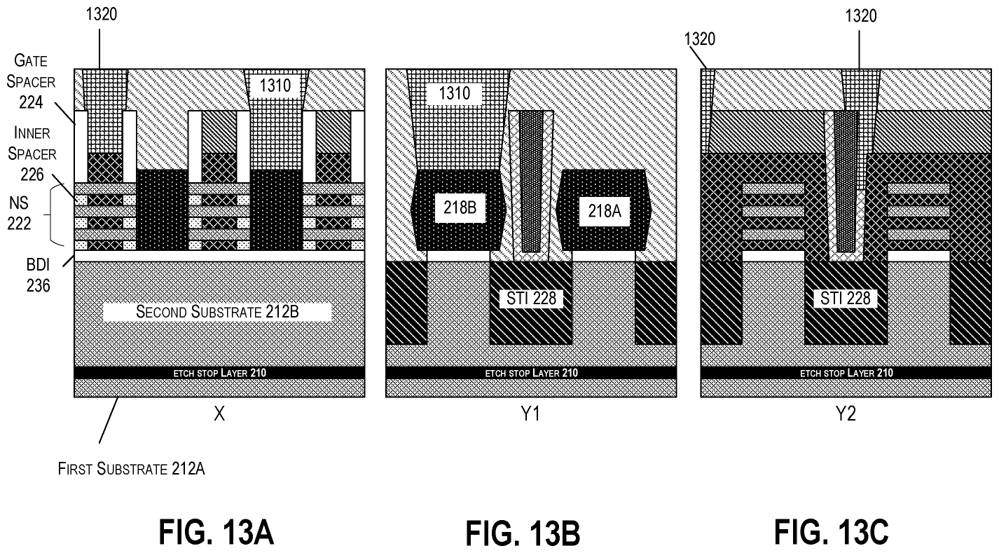

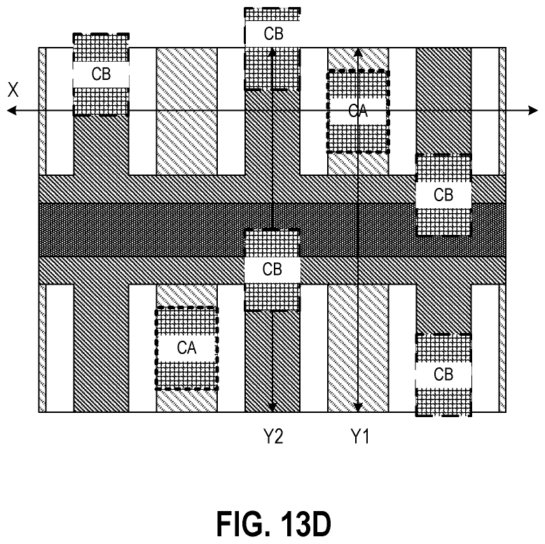

FIGS. 13A-13D illustrate a semiconductor device after the gate contact metallization and the source/drain contact metallization, in accordance with some embodiments. In some embodiments, the OPL is removed and the source/drain contacts 1310 and the gate contacts 1320 are formed by filling the patterned gate contacts and the source/drain contacts with suitable materials.

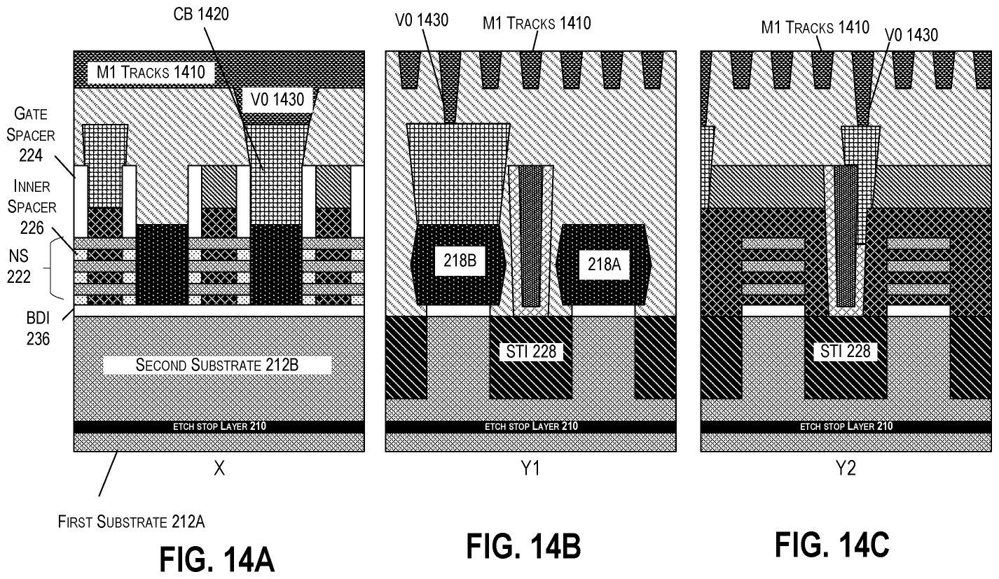

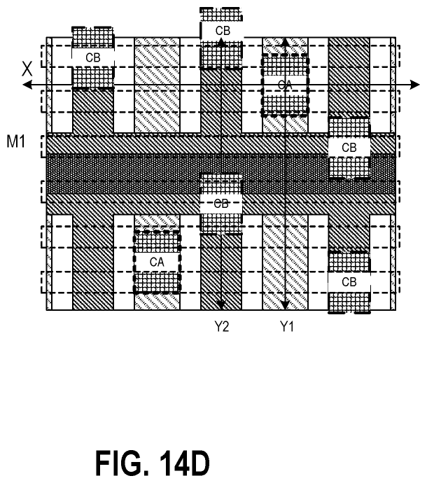

FIGS. 14A-14D illustrate a semiconductor device after the formation of the via and the metal track, in accordance with some embodiments. In some embodiments, the M1 tracks 1410 are formed. The CB 1420 can be in contact with the M1 tracks 1410 through a via, V0 1430, which is formed extending from the M1 tracks 1410 to the CB 1420. Since CB 1420 is located at the edge of the gate channel 1440, the M1 tracks 1410 and the V0 1430 can be used as gate signal tracks.

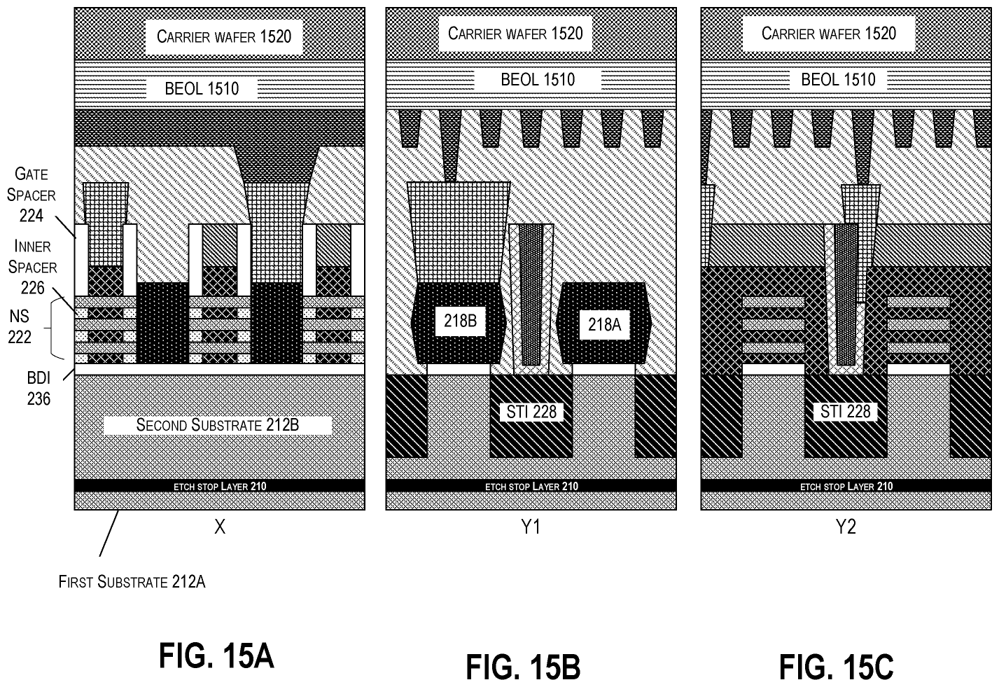

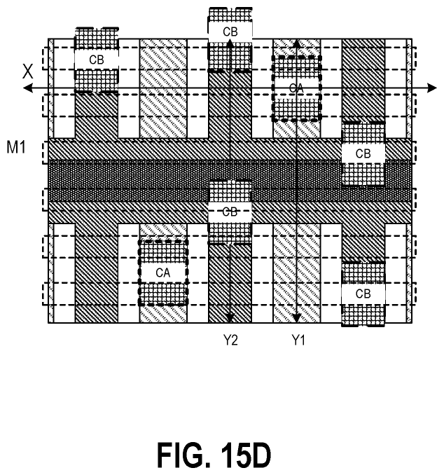

FIGS. 15A-15D illustrate a semiconductor device after the formation of the back end of line, BEOL 1510, and carrier wafer 1520 bonding, in accordance with some embodiments. In some embodiments, carrier wafer bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices.

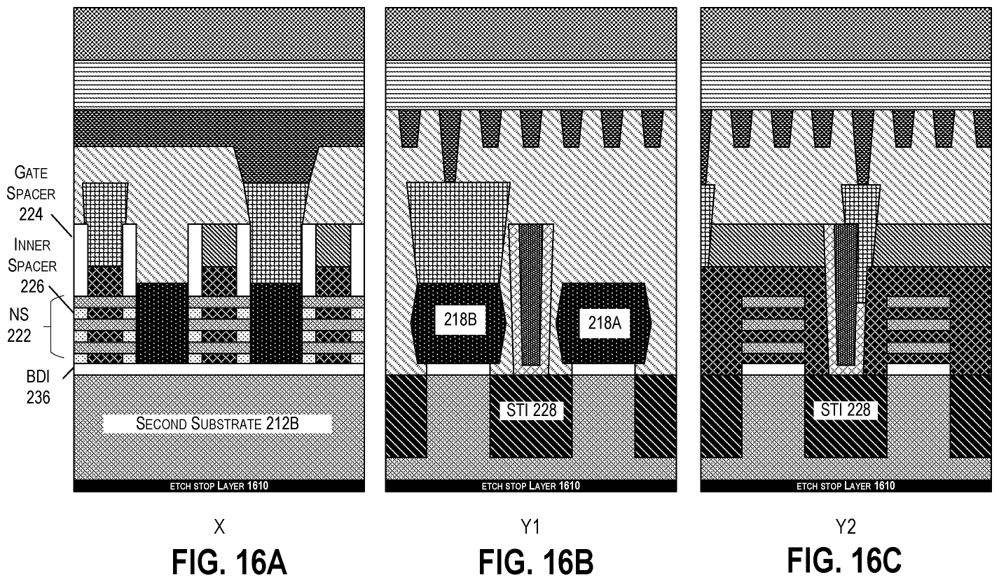

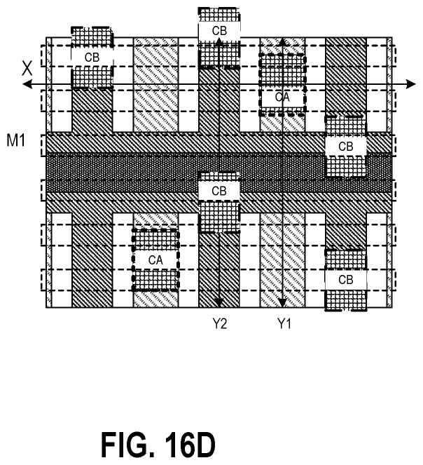

FIGS. 16A-16D illustrate a semiconductor device after the substrate removal, in accordance with some embodiments. In some embodiments, the semiconductor device is flipped (not shown) and the first substrate is removed. The first substrate removal stops at the etch stop layer 1610.

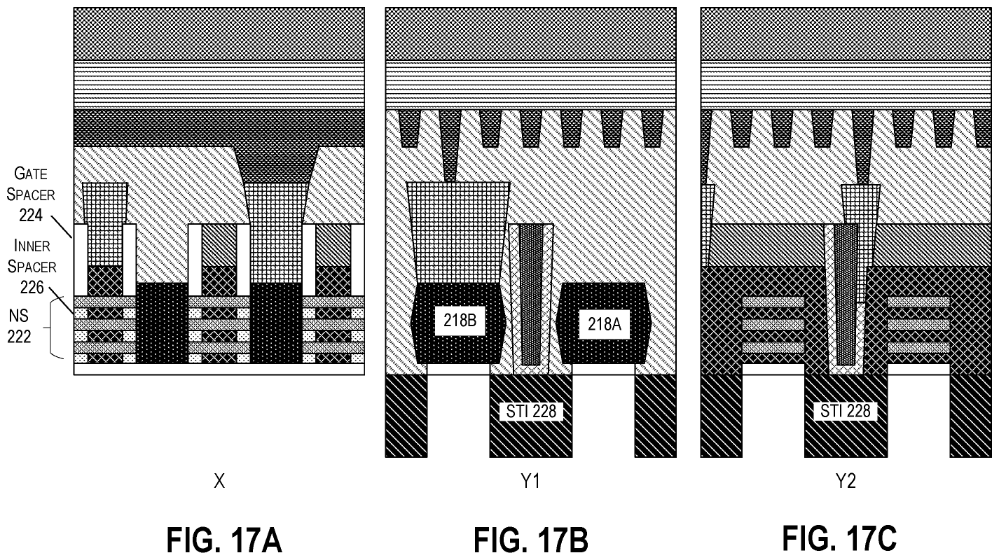

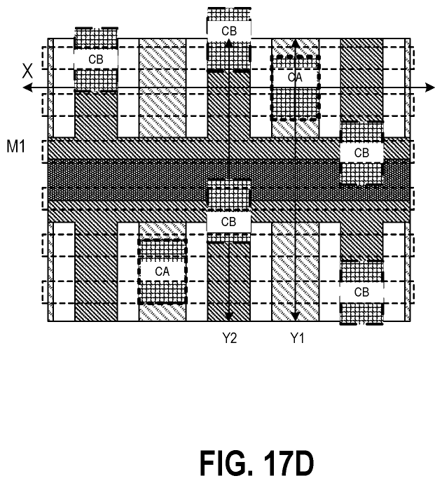

FIGS. 17A-17D illustrate a semiconductor device after the etch stop layer removal, in accordance with some embodiments. In some embodiments, the etch stop layer is removed. Subsequently, the remaining substrate, e.g., the second substrate, is removed from the semiconductor device.

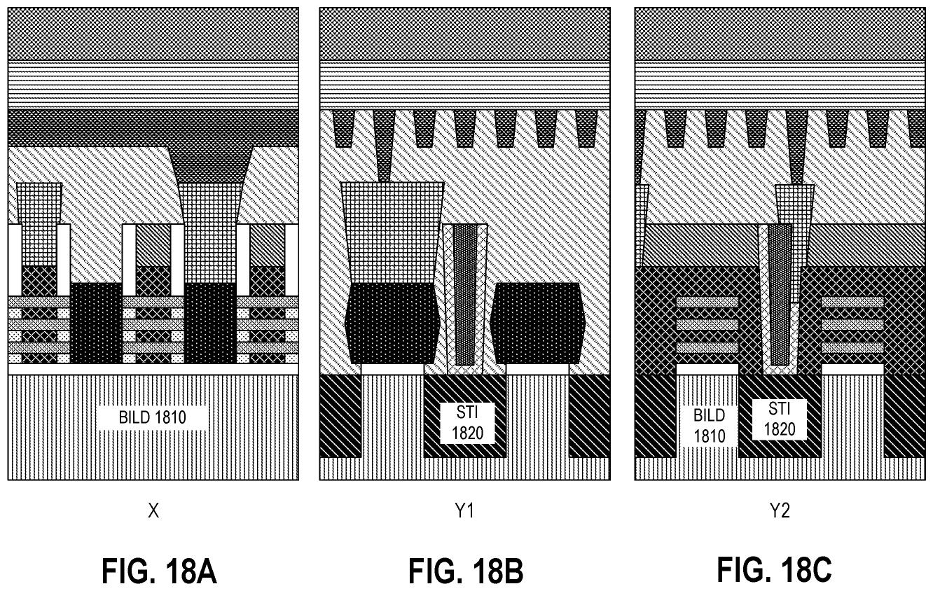

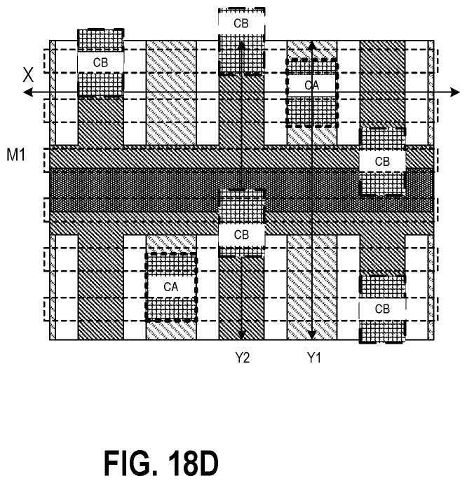

FIGS. 18A-18D illustrate a semiconductor device after the formation of the backside interlayer dielectric, in accordance with some embodiments. In some embodiments, the backside ILD, BILD 1810, is formed below the semiconductor device and surrounds the STI 1820. In an embodiment, a CMP process is further processed after the formation of the BILD 1810. The BILD 1810 can be an insulating material or layer used to isolate and provide electrical insulation between the semiconductor device's active regions and the BSCA, and to prevent unwanted electrical contact between the active regions and the backside contact, ensuring the proper functioning and integrity of the semiconductor device. In various embodiments, the BILD 1810 can act as a protective layer, shielding the active regions of the semiconductor device from external contaminants, moisture, and mechanical stress. The BILD 1810 can further help prevent physical damage, such as scratches or particle contamination, which could adversely affect semiconductor device performance. Additionally, the BILD 1810 can act as a barrier against moisture ingress, which can cause corrosion and degradation of the semiconductor device's components.

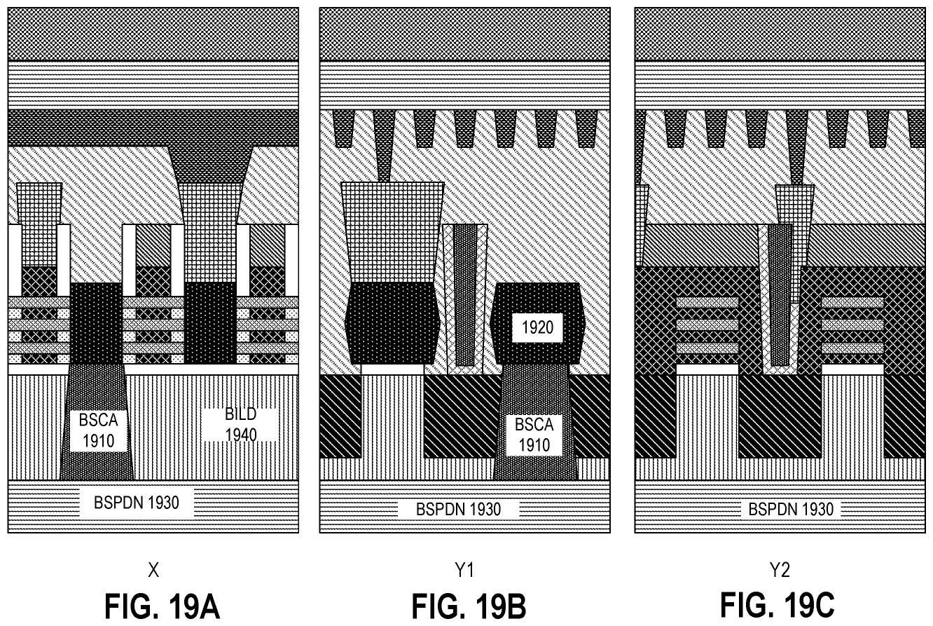

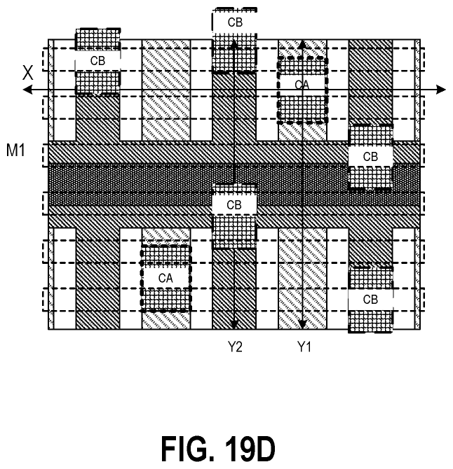

FIGS. 19A-19D illustrate a semiconductor device after the formation of the backside contact and the backside power delivery network, in accordance with some embodiments. In some embodiments, the BSCA 1910 is formed below the first source/drain region 1920 and within a recess, which is formed by removing portions of the BILD, by filling by a metal contact. A backside power delivery network, BSPDN 1930, is formed below the BILD 1940 and the BSCA 1910. The BSPDN 1930 can include conductive metal layers and architecture that distribute power supply voltage and ground lines across the integrated circuit. The backside power grid can complement supply routing on the frontside metal stack. Backside power distribution lines can use thick copper fill between the semiconductor device and package bumps/pillars.

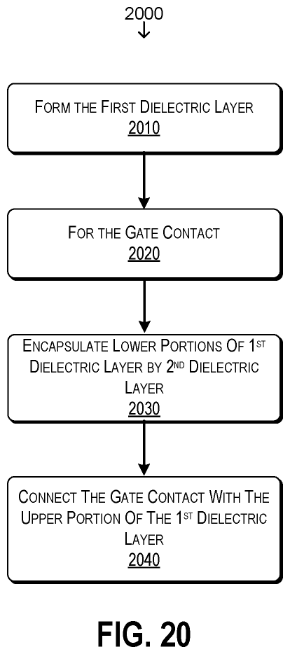

FIG. 20 illustrate a block diagram of a method 2000 for forming the semiconductor device, in accordance with some embodiments. As shown by block 2010, the first dielectric layer is formed. The first dielectric layer is extended vertically between two adjacent gate channels.

As shown by block 2020, the gate contact is formed. The gate contact is formed over a first gate channel of the two adjacent gate channels.

As shown by block 2030, the lower portion of the first dielectric layer is encapsulated by a second dielectric layer, and the second side of the first dielectric layer is covered by the second dielectric layer.

As shown by block 2040, the gate contact is connected to an upper portion of the first side of the first dielectric layer.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a gate contact over a first gate channel of two adjacent gate channels; and
a first dielectric layer encapsulating a lower portion of a second dielectric layer and covering a first side of the second dielectric layer, wherein:
the first dielectric layer is extended vertically between the two adjacent gate channels; and
the gate contact is connected to an upper portion of the first side of the second dielectric layer.

2. The semiconductor device of claim 1, wherein the first dielectric layer is connected to the two adjacent gate channels.

3. The semiconductor device of claim 1, wherein the gate contact further covers portions of a top surface of the second dielectric layer.

4. The semiconductor device of claim 1, further comprising:
a first self-aligned contact (SAC) dielectric cap over the first gate channel of the two adjacent gate channels; and
a second SAC dielectric cap over a second gate channel of the two adjacent gate channels,
wherein the gate contact is connected to the first SAC dielectric cap.

5. The semiconductor device of claim 4, wherein a top surface of portions of the first dielectric layer, a top surface of the second dielectric layer, a top surface of the first SAC dielectric cap, and a top surface of the second SAC dielectric cap are coplanar.

6. The semiconductor device of claim 1, further comprising a backside power delivery network (BSPDN) on a backside of the semiconductor device.

7. The semiconductor device of claim 4, wherein the gate contact is partially etched into the first SAC dielectric cap and the second dielectric layer.

8. The semiconductor device of claim 1, further comprising:
a metal track (M1 track) over the gate contact; and
a via connecting the first gate channel to the M1 track via the gate contact, wherein the M1 track is a signal track.

9. The semiconductor device of claim 1, wherein the gate contact is located at a negative field-effect transistor (NFET) to NFET cell boundary, or at a positive FET (PFET) to PFET cell boundary.

10. The semiconductor device of claim 4, wherein the first SAC dielectric cap and the second SAC dielectric cap are made of silicon nitride.

11. The semiconductor device of claim 1, wherein the first dielectric layer is made of silicon dioxide and the second dielectric layer is made of silicon nitride.

12. A method for fabrication of a semiconductor device, the method comprising:
forming a gate contact over a first gate channel of two adjacent gate channels;
encapsulating a lower portion of a second dielectric layer by a first dielectric layer;
covering a first side of the second dielectric layer by first second dielectric layer; and
connecting the gate contact to an upper portion of the first side of the second dielectric layer,
wherein the first dielectric layer is extended vertically between the two adjacent gate channels.

13. The method of claim 12, further comprising connecting the first dielectric layer to a second gate channel of the two adjacent gate channels.

14. The method of claim 12, further comprising covering portions of a top surface of the second dielectric layer by the gate contact.

15. The method of claim 12, further comprising:
forming a first self-aligned contact (SAC) dielectric cap over the first gate channel of the two adjacent gate channels;
forming a second SAC dielectric cap over a second gate channel of the two adjacent gate channels; and
connecting the gate contact to the first SAC dielectric cap.

16. The method of claim 15, further comprising forming a backside power delivery network (BSPDN) on a backside of the semiconductor device.

17. The method of claim 15, further comprising partially etched the gate contact into the first SAC dielectric cap and the second dielectric layer.

18. The method of claim 12, further comprising:
forming a metal track (M1 track) over the gate contact; and
forming a via connecting the first gate channel to the M1 track via the gate contact.

19. The method of claim 12, further comprising forming the gate contact at a negative field-effect transistor (NFET) to NFET cell boundary, or at a positive FET (PFET) to PFET cell boundary.

20. A semiconductor device, comprising:
a dielectric structure between a first gate channel and a second gate channel;
a gate contact over the first gate channel and covering an upper portion of the dielectric structure; and
a first self-aligned contact (SAC) dielectric cap and a second SAC dielectric cap over the first gate channel and the second gate channels, respectively.
